(19) United States
(12) Patent Application Publication
(10) Pub. No.: US 2023/0039295 A1
(43) Pub. Date: Feb. 9, 2023

(54) METHOD FOR MANUFACTURING AN IMAGE SENSOR

(71) Applicant: Soitec, Bemin (FR)

(72) Inventors: Walter Schwarzenbach, Bernin (FR); David Herisson, Bernin (FR); Alain Delpy, Bernin (FR)

(21) Appl. No.: 17/758,848

(22) PCT Filed: Jan. 14, 2021
(86) PCT No.: PCT/FR2021/050059

§ 371 Date: Jul. 14, 2022

(30) Foreign Application Priority Data
Jan. 15, 2020 (FR) FR2000345

(51) Int. Cl. H01L 27/146

(52) U.S. Cl. CPC H01L 27/14687

(57) ABSTRACT

A method for fabricating an image sensor, comprising: providing a receiver substrate comprising a base substrate and an active layer comprising pixels, each pixel comprising a doped region for collecting the electric charges generated in the pixel, the receiver substrate being devoid of metal interconnections, providing a donor substrate comprising a weakened zone limiting a monocrystalline semiconductor layer, bonding the donor substrate to the receiver substrate, detaching the donor substrate along the weakened zone, so as to transfer the semiconductor layer to the receiver substrate, implementing a finishing treatment on the transferred monocrystalline semiconductor layer, the finishing treatment comprising (i) thinning of the transferred monocrystalline semiconductor layer by sacrificial oxidation followed by chemical etching and (ii) smoothing of the transferred monocrystalline semiconductor layer by means of at least one rapid anneal.

### CROSS-REFERENCE TO RELATED APPLICATIONS

This application is a national phase entry under 35 U.S.C. § 371 of International Patent Application PCT/FR2021/050059, filed Jan. 14, 2021, designating the United States of America and published as International Patent Publication WO 2021/144534 A1 on Jul. 22, 2021, which claims the benefit under Article 8 of the Patent Cooperation Treaty to French Patent Application Serial No. FR2000345, filed Jan. 15, 2020.

### TECHNICAL FIELD

The present disclosure relates to a process for fabricating an image sensor.

### BACKGROUND

The fabrication of an image sensor by three-dimensional (3D) integration involves successively stacking various layers comprising, in particular, photodiodes, each of which defines a pixel of the image sensor, components of the readout circuit for reading out the pixels and interconnections between the components and the pixels.

Reference may be made, for example, to [Mansoorian 2009] for the description of an image sensor formed by 3D integration.

FIG. 1 schematically shows an image sensor in cross section.

The sensor successively comprises:
a base substrate 10,
an active layer comprising a plurality of pixels 11; each pixel comprises a doped region 12 suitable for collecting the electric charges generated in each pixel; the pixels are separated from one another by electrically isolating trenches 13,
one or more dielectric or electrically insulating layers 14, for example, silicon nitride or silicon oxide,
a silicon layer 22, which comprises components 25 of the pixel readout circuit.

Interconnections 26 run through the layer 14 in order to electrically connect the components 25 and the pixels 11.

However, a 3D integration process has substantial limitations. Thus, in a conventional approach of bonding and consuming a sacrificial substrate, the process bears the cost of consuming such a substrate. In an approach comprising a layer transfer, for example, using the SMARTCUT™ process, the thermal budget of the successive steps has to be controlled so as not to damage the active zones or the components formed previously. Generally speaking, and according to the references available in the literature, an overly high thermal budget is liable to bring about abnormal diffusion from the doped regions that are configured to collect the electric charges photogenerated in the pixel, which may affect the performance of the sensor. Similarly, metal connections between elements of the sensor are liable to be damaged by an overly high thermal budget.

However, implementing steps with a low thermal budget may be disadvantageous, in particular, in terms of duration and/or cost of the process.

### BRIEF SUMMARY

An aim of the present disclosure is to design a process for fabricating an image sensor using 3D integration technology, in which the control of the thickness of the added layer is compatible with an FDSOI-type substrate, which can be rapidly industrialized and is inexpensive while preventing the diffusion of the dopants present in the electric-charge collection regions and in the doped layer of amorphous silicon.

An SOI (“semiconductor-on-insulator”) substrate is a substrate comprising a semiconductor layer, for example, made of silicon, on a substrate, an electrically insulating layer being inserted between the semiconductor layer and the substrate. In an FDSOI (“fully depleted semiconductor-on-insulator”) substrate, the thickness of the semiconductor layer is thin enough to allow complete depletion of the conduction channel of a transistor formed in the layer. Such a layer typically has a thickness of a few tens of nanometers.

To that end, the present disclosure proposes a process for fabricating an image sensor, comprising:
providing a receiver substrate comprising a base substrate and an active layer comprising pixels, each pixel comprising a doped region for collecting the electric charges generated in the pixel, the receiver substrate being devoid of metal interconnections,

providing a donor substrate comprising a weakened zone delimiting a monocrystalline semiconductor layer,

bonding the donor substrate to the receiver substrate,

detaching the donor substrate along the weakened zone so as to transfer the semiconductor layer to the receiver substrate,

implementing a finishing treatment on the transferred semiconductor layer, the finishing treatment comprising (i) thinning of the transferred layer by sacrificial oxidation followed by chemical etching and (ii) smoothing of the transferred semiconductor layer by way of at least one rapid anneal.

What is meant by “rapid anneal” in the present text is a heat treatment having a temperature ramp-up at a rate of more than 10° C. per second, preferably on the order of 50° C. per second or even more.

That the receiver substrate comprises only doped zones and no metal interconnections makes certain heat treatments acceptable for smoothing the transferred semiconductor layer, although the heat treatments should have a sufficiently moderate thermal budget so as not to bring about diffusion of the dopants present in the receiver substrate. A rapid anneal, such as implemented in embodiments the present disclosure, observes this constraint.

Additionally, the controlled chemical etching provides the uniformity of thickness required for the target application. This uniformity of thickness is similar to that of FDSOI substrates, for which the criterion of uniformity may be expressed, on the one hand, by the variability in the thickness of the transferred layer within one and the same substrate or wafer, the intra-wafer variability typically being lower than or equal to 10 Å, and, on the other hand, by the variability in the mean thickness of the transferred layer between different wafers, the inter-wafer variability typically being on the order of ±2 Å at most.

Particularly advantageously, each rapid anneal is controlled in order to prevent diffusion of the dopants from the doped regions of the pixels.

To that end, each rapid anneal may be implemented at a temperature of between 1100 and 1250° C. for a duration of between 15 and 60 s.

In some embodiments, the sacrificial oxidation and the chemical etching are controlled in order to thin the transferred monocrystalline semiconductor layer to a thickness of between 10 and 100 nm.

The chemical etching for thinning the transferred monocrystalline semiconductor layer may be implemented by way of a wet etching, a plasma dry etching, an ion-beam dry etching or a cluster-ion-beam dry etching.

In some embodiments, the process further comprises, after the finishing of the transferred monocrystalline semiconductor layer, the formation of components of a readout circuit for reading out the pixels in or on the transferred semiconductor layer.

In some embodiments, the process further comprises, after the finishing of the transferred monocrystalline semiconductor layer, the formation of interconnections between the pixels and the components of the pixel readout circuit.

In some embodiments, the process comprises the formation of the weakened layer by implanting atomic species into the donor substrate.

In some embodiments, the finishing treatment successively comprises:
(i) a first rapid anneal,
(ii) removal of defects related to the implantation by sacrificial oxidation of the transferred layer,
(iii) a second rapid anneal, and
(iv) the thinning of the transferred layer.

In some embodiments, the donor substrate further comprises, on the monocrystalline semiconductor layer, a layer of silicon oxide, preferably deposited via tetraethyl orthosilicate (TEOS).

The donor substrate may further comprise one or more electrically insulating or semiconductor layers (or a stack of both of these types of layers) on the layer of silicon oxide. In the case of a semiconductor layer, it may be crystalline or amorphous, doped (n+or p+) or undoped.

In some embodiments, the layer of silicon oxide, or the layer or stack of layers arranged on the layer of silicon oxide, is deposited on the donor substrate before the implantation.

In some embodiments, the receiver substrate further comprises one or more electrically insulating or semiconductor layers (or a stack of both of these types of layers) on the active layer. Preferably, at least one electrically insulating layer is a layer of silicon oxide and the semiconductor layer may be crystalline or amorphous, doped (n+or p+) or undoped.

Particularly advantageously, each rapid anneal has a temperature ramp-up rate of more than 10° C. per second, preferably more than or equal to 50° C. per second.

Preferably, the smoothing comprises no heat treatment having a temperature ramp-up rate of less than 10° C. per second.

In some embodiments, the smoothing is implemented individually for each structure comprising the semiconductor layer and the receiver substrate.

### BRIEF DESCRIPTION OF THE DRAWINGS

Further features and advantages of the present disclosure will become apparent from the following detailed description, with reference to the accompanying drawings, in which:

FIG. 1 schematically shows an image sensor in cross section;

FIG. 2 schematically shows, in cross section, a receiver substrate and a donor substrate as used in a process for fabricating an image sensor according to one embodiment of the present disclosure;

FIG. 3 schematically shows, in cross section, the receiver substrate and the donor substrate of FIG. 2 after detachment of the donor substrate along the weakened zone;

FIG. 4 schematically shows, in cross section, the image sensor formed from the donor and receiver substrates of FIG. 3, after finishing of the transferred semiconductor layer and formation of the readout circuit for reading out the pixels and the interconnections;

FIG. 5 is a SIMS profile of the phosphorus concentration within an SOI structure comprising a phosphorus-doped layer following a rapid anneal such as implemented in embodiments of the present disclosure and a heat treatment such as implemented during the fabrication of an FDSOI substrate.

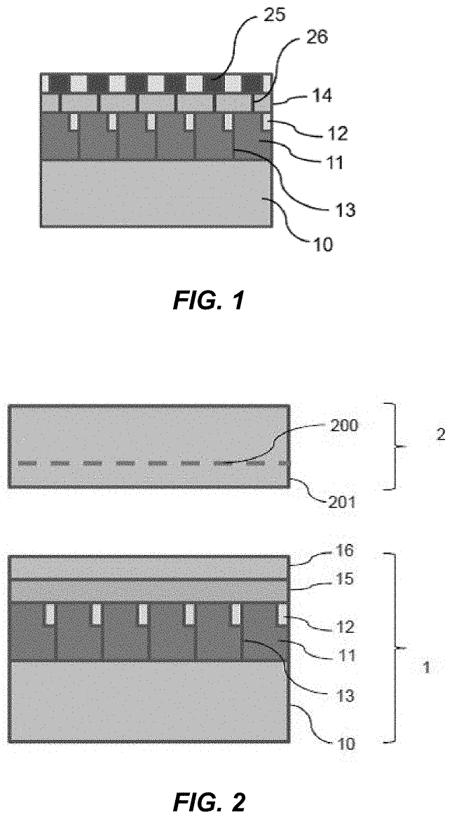

Reference signs that are identical from one figure to the next denote elements that are identical or perform the same function.

To make the figures clearer, the various elements are not necessarily shown to scale.

### DETAILED DESCRIPTION

The present disclosure proposes fabricating an image sensor by transferring a thin layer from a donor substrate to a receiver substrate.

The receiver substrate comprises a base substrate and an active layer comprising a plurality of pixels.

The base substrate is generally a semiconductor substrate, for example, of silicon. The base substrate acts, in particular, as the mechanical carrier for the image sensor.

The active layer is a monocrystalline semiconductor layer, for example, of silicon or of silicon-germanium.

The pixels are separated from one another by electrically isolating trenches. These trenches are known by the acronym DTI for “deep trench isolation” or CDTI for “capacitor deep trench isolation.”

Each pixel comprises a doped region suitable for collecting the electric charges generated in each pixel.

Particularly advantageously, the receiver substrate comprises no metal interconnections between its components.

The fabrication of such a receiver substrate is within the competence of a person skilled in the art. The process for fabricating the receiver substrate will therefore not be described in detail in the present text.

The donor substrate comprises a weakened zone, which delimits a monocrystalline semiconductor thin layer. In some embodiments, the donor substrate may be a bulk substrate, consisting of a single monocrystalline semiconductor material. Alternatively, the donor substrate may be a composite substrate including at least two layers of different materials, comprising at least one monocrystalline semiconductor layer. The monocrystalline thin layer may be a layer of silicon, or of another semiconductor material.

The weakened zone is advantageously formed by implanting atomic species, such as hydrogen and/or helium atoms, into the donor substrate. Determining the dose and the energy for implantation in order to form the weakened zone at a given depth of the donor substrate is within the capabilities of those of ordinary skill in the art. During implantation, the surface of the donor substrate may potentially be protected by a dielectric layer, such as a layer of silicon oxide (SiO₂). The layer may then be removed, for example, by selective etching.

The donor substrate is then bonded to the receiver substrate. In some embodiments, the bonding may be performed via a dielectric layer, such as a layer of silicon oxide.

A fracture in the donor substrate is initiated at the site of the weakened zone, leading to the detachment of the donor substrate along the weakened zone. Upon completion of this detachment, the semiconductor thin layer has been transferred to the receiver substrate.

This process is well known as the SMARTCUT™ process.

The final product comprising the receiver substrate and the semiconductor thin layer will be called the wafer in the present text.

Since the transferred semiconductor thin layer exhibits a certain degree of roughness, a finishing treatment is implemented on the wafer in order to smooth the layer while providing the required uniformity of thickness.

To avoid causing the diffusion of dopants from the active layer, this entire finishing treatment is implemented with a moderate thermal budget, lower than that usually implemented to fabricate FDSOI substrates. However, given that the receiver substrate comprises no metal, it is not necessary to use a low-temperature treatment, such as described, for example, in [Schwarzenbach 2019], which has the drawback of being lengthy and complex.

The target thickness for the transferred semiconductor layer is between 10 nm and 100 nm, with a maximum variation of ±5 Å with respect to the target value, within each wafer and between the different wafers fabricated using the process. This criterion of uniformity is generally required for the fabrication of FDSOI substrates, but cannot be obtained for the target image sensor with the usual finishing treatment for FDSOI substrates, which has an overly high thermal budget. Specifically, the finishing treatment for FDSOI substrates typically comprises a “batch anneal” process, which is a lengthy, high-temperature smoothing process, advantageously carried out in a furnace allowing a plurality of substrates to be treated at the same time (hence the term “batch”). Such a “batch anneal” is typically implemented at a temperature of between 1150 and 1200° C. for a duration of a few minutes, generally longer than 15 minutes. Furthermore, the temperature ramp-up in the furnace is relatively slow, with a ramp-up on the order of a few ° C. per minute, which contributes to increasing the thermal budget to which the substrate is subjected. This smoothing allows the transferred semiconductor layer to be brought to a level of surface roughness that is compatible with the fabrication of transistors. However, it has been demonstrated that such a “batch anneal” has the effect of degrading the uniformity of the thickness of the transferred semiconductor layer within one and the same wafer.

Concretely, the finishing treatment implemented in the present disclosure comprises, on the one hand, thinning of the transferred layer by sacrificial oxidation followed by chemical etching and, on the other hand, smoothing by way of one or more rapid anneals, which offer a lower thermal budget than that of a “batch anneal,” the thermal budget being suitable for preserving the integrity of the pixels.

Regarding the thinning, the treatment firstly comprises oxidation of the transferred layer so as to form a thin layer of oxide on the surface of the layer. This oxide is preferably formed by thermal oxidation of the material of the semiconductor layer, in which the transferred semiconductor layer is subjected to a heat treatment in an oxidizing atmosphere comprising oxygen and/or water vapor, which results in a surface portion of the layer being consumed. By adjusting the conditions of this thermal oxidation (in particular, its duration, its atmosphere (dry or wet), its pressure and its temperature), it is possible to adjust the thickness of the transferred layer consumed, and therefore the extent to which the layer is thinned. The oxidation is implemented at a temperature of less than 1000° C. and preferably less than or equal to 950° C. so as not to bring about diffusion of the dopants within the wafer. The duration of the oxidation is chosen according to the thickness of the oxide to be formed, which depends on the initial thickness of the transferred layer and on the target thickness of the layer. Such oxidation may be implemented simultaneously on one or more batches of wafers.

Next, the thickness of the transferred layer covered with the oxide layer is measured at a certain number of points distributed over the surface of the wafer. Thus, measurement by ellipsometry or by reflectometry gives the thickness of the semiconductor layer.

To define the treatment to be applied to the transferred semiconductor layer in order to make its thickness uniform, a map of the thickness of the layer obtained by way of ellipsometry or reflectometry is used. From the thicknesses measured at various points on the wafer, it is also possible to determine the mean thickness of the semiconductor layer.

This thickness map and/or this mean thickness make it possible to determine one or more regions of the transferred layer that exhibit excess thicknesses with respect to a target thickness and that consequently have to undergo thinning in order to improve the uniformity of thickness of the transferred semiconductor layer.

Depending on the circumstances, the uniformity of interest may be the “intra-wafer” uniformity (i.e. that over the surface of one and the same structure, the structure generally taking the shape of a circular wafer) and/or the “inter-wafer” uniformity (i.e. that between all of the structures belonging to all of the production batches).

In the case of intra-wafer uniformity, the measured thickness is compared, at each point, with the target thickness of the desired final product, the target thickness being less than or equal to the mean thickness. In this case, the one or more regions to be thinned are therefore the one or more regions in which the thickness of the semiconductor layer is greater than the target thickness, the one or more excess thicknesses corresponding to the difference between the measured thickness and the target thickness. It is therefore here a question of one or more “local” excess thicknesses of the wafer.

In the case of inter-wafer uniformity, the mean of the thicknesses of the semiconductor layer that are measured at the various measurement points is compared with a target mean thickness. In this case, a wafer to be thinned is a wafer for which the mean thickness of the semiconductor layer is greater than the target mean thickness, the excess thickness corresponding to the difference between these two mean thicknesses. It is therefore here a question of an “overall” excess thickness of the wafer.

Of course, these uniformity imperatives may be combined.

To thin these regions in a localized manner within one wafer and/or to thin the wafer overall, selective etching of the layer of sacrificial oxide is implemented first of all. For this, an etchant suitable for etching the sacrificial oxide without attacking the semiconductor material of the layer is used. Typically, if the layer of sacrificial oxide is made of silicon oxide and the transferred layer is made of silicon, a solution of hydrofluoric (HF) acid is used as the etchant. Of course, a person of ordinary skill in the art will be able to select any other appropriate etchant according to the respective materials of the layer of sacrificial oxide and of the semiconductor layer.

Once the layer of sacrificial oxide has been removed, chemical etching of the semiconductor layer itself is implemented.

In some embodiments, the etching is a wet etching, i.e. one in which the transferred semiconductor layer is exposed to an etching solution. Exposure may be achieved by immersing the wafer in the solution, or by spraying the etching solution onto the surface of the wafer by way of a nozzle, which may allow the etching to be localized to regions that have to be thinned with respect to other regions of the wafer.

This etching may be implemented at ambient temperature, i.e. on the order of 20 to 25° C., or at a higher temperature, but generally less than 80° C.

In other embodiments, the etching may be a plasma dry etching, an ion-beam dry etching (or RIE, RIE for “reactive-ion etching”), or a cluster-ion-beam dry etching (or GCIB etching, GCIB for “gas cluster ion beam”). These steps do not entail a significant thermal budget.

The parameters of implementation of these various types of etchings allow the transferred semiconductor layer to be thinned overall and/or in a localized manner.

Such a process for thinning an FDSOI substrate and making it uniform, which remedies the degradation in the uniformity of thickness of the transferred semiconductor layer caused by the smoothing by “batch anneal,” is described in patent FR 2 991 099.

Regarding the smoothing, it is performed, in embodiments of the present disclosure, by way of one or two high-temperature RTAs (RTA for “rapid thermal annealing”). Each anneal is typically implemented at a temperature of between 1100 and 1250° C. for a duration of between 15 and 60 s, which allows reorganization of the atoms at the surface of the transferred semiconductor layer and thus smooths it. In contrast to a “batch anneal,” each rapid annealing is implemented with a rapid temperature ramp-up, on the order of a few tens of ° C. per second. Additionally, while a “batch anneal” is implemented simultaneously on a plurality of wafers, a rapid annealing is implemented individually on each wafer.

The thermal budget implemented in these one or more annealing steps is low enough to avoid diffusion of the dopants within the wafer.

Preferably, the process comprises two rapid annealing steps, in order to obtain an optimal surface state of the transferred layer.

Thus, unlike the known process for fabricating FDSOI substrates, the smoothing implemented in embodiments of the present disclosure does not comprise a “batch anneal.” More generally, the smoothing does not comprise a slow heat treatment, i.e. one having a temperature ramp-up rate of less than 10° C. per second. The integrity of the pixels is therefore preserved during the smoothing.

According to one preferred embodiment, the process comprises two steps of sacrificial oxidation, implemented, respectively, between the first and the second rapid annealing and after the second rapid annealing when two rapid annealing steps are implemented. The first sacrificial oxidation advantageously makes it possible to remove the defects linked to the weakening implantation by oxidizing a surface region of the transferred layer and then removing the oxidized region, while the second sacrificial oxidation, which is followed by chemical etching of the transferred layer, makes it possible to uniformly thin the transferred layer to the target thickness. The rapid annealing steps are preferably implemented before the thinning of the transferred layer, in order to preserve the stability of the layer. It would be possible to envisage omitting the first rapid annealing but this would be at the cost of a deterioration in the roughness.

After the finishing of the transferred semiconductor layer, it is possible to fabricate components of the pixel readout circuit in or on this layer.

The components are furthermore electrically connected to the pixels by interconnections. The interconnections may be made of metal but, given that they are formed after the finishing treatment for the transferred semiconductor layer, they do not risk being damaged thereby.

To produce the image sensor, it may be useful to insert one or more additional semiconductor and/or electrically insulating layers between the active layer and the semiconductor layer comprising the components of the readout circuit.

These additional layers may be integrated into the image sensor in various ways.

According to one embodiment, the additional layers may be formed on the active layer of the receiver substrate, before the bonding of the donor substrate. These layers may be formed, for example, by deposition. Whatever the formation process chosen, it does not entail a thermal budget that is liable to cause the dopants to diffuse from the active layer.

According to another embodiment, at least one of the additional layers may be formed by deposition on the active layer of the receiver substrate and at least one other of the additional layers is formed by deposition on the monocrystalline semiconductor layer of the donor substrate, before the bonding of the substrates. As mentioned above, the deposition of each additional layer on the active layer of the receiver substrate has to be performed with a thermal budget that is low enough not to bring about diffusion of the dopants.

According to yet another embodiment, the additional layers are formed on the donor substrate. Preferably, the layers are formed by deposition before the implantation of atomic species for forming the weakened zone. Thus, the thermal budget of these depositions does not risk causing premature fracturing of the donor substrate along the weakened zone. If the additional layers are deposited after the formation of the weakened zone, the thermal budget applied will have to be limited in order to avoid such premature fracturing.

FIG. 2 is a schematic view in cross section of the donor substrate and the receiver substrate before their bonding in one embodiment of the present disclosure.

The receiver substrate 1 successively comprises:
a base substrate 10,
an active layer comprising a plurality of pixels 11, each pixel comprising a doped region 12 suitable for collecting the electric charges generated in each pixel; the pixels are separated from one another by electrically isolating trenches 13,
a first additional layer 15, for example, a semiconductor layer, and
a second additional layer 16, for example, an electrically insulating layer.

The donor substrate 2 comprises a weakened zone 200 delimiting a semiconductor layer 201.

As mentioned above, the layer 16, and potentially the layer 15, could be formed on the donor substrate 2 instead of the receiver substrate 1. In this case, each layer concerned is intended to be transferred to the receiver substrate with the semiconductor layer 201.

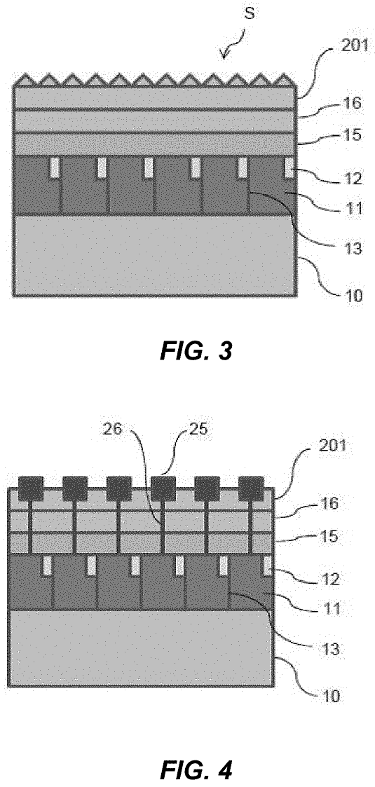

With reference to FIG. 3, the donor substrate is bonded to the receiver substrate, and then the donor substrate is detached along the weakened zone so as to transfer the semiconductor layer 201 to the receiver substrate 1.

As shown schematically, the surface S of the semiconductor layer 201 after detachment is rough.

The finishing treatment described above is therefore implemented.

Once the transferred monocrystalline semiconductor layer has been thinned uniformly to the target thickness, components 25 of the readout circuit are formed in or on the layer (see FIG. 4). Interconnections 26 between the components 25 and the pixels 11 are also formed.

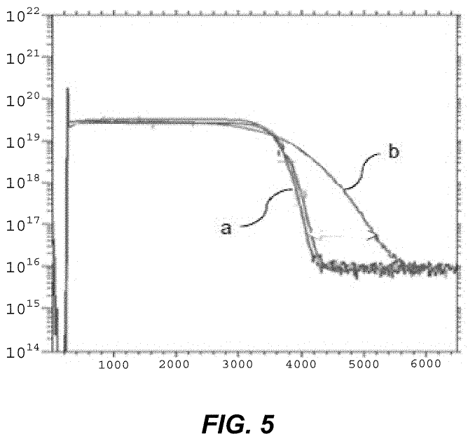

FIG. 5 is a SIMS (secondary ion mass spectrometry) profile of the phosphorus concentration within an SOI structure successively comprising, from its surface, a layer of undoped monocrystalline silicon with a thickness of 42 nm, a layer of silicon oxide with a thickness of 190 nm, a phosphorus-doped silicon layer extending to a depth of 3500 nm, and a base substrate made of silicon that is not intentionally doped, following two rapid anneals at 1200° C. for 30 seconds, such as implemented in embodiments of the present disclosure (curve a), and a heat treatment (“batch anneal”) at 1200° C. for 5 minutes, such as implemented in the fabrication of an FDSOI substrate (curve b). The abscissa gives the depth (in nm) from the surface of the SOI structure, and the ordinate gives the phosphorus concentration (in at/cm²).

The sharp transition (substantially vertical slope) between the doped layer and the base substrate visible in curve a shows that there has been substantially no diffusion of dopants during the rapid anneals. Conversely, the more gradual transition visible in curve b indicates diffusion of dopants from the doped layer to the base substrate.

These curves therefore show the protective effect of the one or more rapid anneals in comparison with the convention heat treatment with respect to the doped regions.

### REFERENCES

[Mansoorian 2009]: Mansoorian, B., and D. Shaver, with Suntharalingam, V. et al., Lin Ping Ang. “A 4-side Tileable Back Illuminated 3D-integrated Mpixel CMOS Image Sensor.” Solid-State Circuits Conference—Digest of Technical Papers, 2009. ISSCC 2009. IEEE International. 2009. 38-39, 39a.

[Schwarzenbach 2019]: W. Schwarzenbach et al, “Low Temperature SMARTCUT™ enables High Density 3D SoC Applications,” Proc. ICICDT Conf., 17-19 Jun. 2019

FR 2 991 099

1. A method for fabricating an image sensor, comprising:
providing a receiver substrate comprising a base substrate and an active layer comprising pixels, each pixel comprising a doped region for collecting electric charges generated in the pixel, the receiver substrate being devoid of metal interconnections;
providing a donor substrate comprising a weakened zone delimiting a monocrystalline semiconductor layer;
bonding the donor substrate to the receiver substrate;
detaching the donor substrate along the weakened zone so as to transfer the semiconductor layer to the receiver substrate; and
implementing a finishing treatment on the transferred monocrystalline semiconductor layer, the finishing treatment comprising thinning of the transferred monocrystalline semiconductor layer by sacrificial oxidation followed by chemical etching and smoothing of the transferred monocrystalline semiconductor layer by way of at least one rapid annealing.

2. The method of claim 1, wherein each rapid annealing is controlled to prevent diffusion of dopants from the doped regions of the pixels.

3. The method of claim 1, wherein each rapid annealing is implemented at a temperature of between 1100 and 1250° C. for a duration of between 15 and 60 s.

4. The method of claim 1, wherein the sacrificial oxidation and the chemical etching are controlled to thin the transferred monocrystalline semiconductor layer to a thickness of between 10 and 100 nm.

5. The method of claim 1, wherein the chemical etching for thinning the transferred monocrystalline semiconductor layer is implemented by way of a wet etching, a plasma dry etching, an ion-beam dry etching or a cluster-ion-beam dry etching.

6. The method of claim 1, further comprising, after the finishing of the transferred monocrystalline semiconductor layer, the formation of components of a readout circuit for reading out the pixels in or on the transferred monocrystalline semiconductor layer.

7. The method of claim 6, further comprising, after the finishing of the transferred monocrystalline semiconductor layer, the formation of interconnections between the pixels and the components of the pixel readout circuit.

8. The method of claim 1, further comprising the formation of the weakened zone by implanting atomic species into the donor substrate.

9. The method of claim 8, wherein the finishing treatment successively comprises:
(i) a first rapid annealing;
(ii) removal of defects related to the implantation by sacrificial oxidation of the transferred monocrystalline semiconductor layer;
(iii) a second rapid annealing; and
(iv) the thinning of the transferred monocrystalline semiconductor layer.

10. The method of claim 1, wherein the donor substrate further comprises at least one electrically insulating layer on the monocrystalline semiconductor layer.

11. The method of claim 1, wherein the donor substrate further comprises at least one semiconductor layer on the monocrystalline semiconductor layer.

12. The method of claim 10, further comprising the formation of the weakened zone by implanting atomic species into the donor substrate, and wherein the electrically insulating layer or the semiconductor layer, respectively, is deposited on the donor substrate before the implantation.

13. The method of claim 1, wherein the receiver substrate further comprises a semiconductor layer on the active layer.

14. The method of claim 1, wherein the receiver substrate further comprises an electrically insulating layer on the active layer.

15. The method of claim 1, wherein each rapid annealing has a temperature ramp-up rate of more than 10° C. per second.

16. The method of claim 1, wherein the smoothing comprises no heat treatment having a temperature ramp-up rate of less than 10° C. per second.

17. The method of claim 1, wherein the smoothing is implemented individually for each structure comprising the semiconductor layer and the receiver substrate.

18. The method of claim 11, further comprising the formation of the weakened zone by implanting atomic species into the donor substrate, and wherein the electrically insulating layer or the semiconductor layer, respectively, is deposited on the donor substrate before the implantation.

19. The method of claim 15, wherein each rapid annealing has a temperature ramp-up rate of more than 50° C. per second.
